(19) United States
(12) Patent Application Publication
(10) Pub. No.: US 2018/0061340 A1
(43) Pub. Date: Mar. 1, 2018

(54) GATE DRIVING CIRCUIT AND DRIVING METHOD, DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: Yingmeng MIAO, Beijing (CN); Yujie GAO, Beijing (CN)

(21) Appl. No.: 15/526,978

(22) PCT Filed: Sep. 27, 2016
(86) PCT No.: PCT/CN2016/100315

§ 371 Date: May 15, 2017

(30) Foreign Application Priority Data
Jan. 7, 2016 (CN) 201610009563.6

(51) Int. Cl. G09G 3/36; H01L 27/12; G02F 1/1362

(52) U.S. Cl. CPC G09G 3/3648; H01L 27/124; G09G 2310/0243; G09G 2300/0809; G09G 2310/0264; G02F 1/1362

(57) ABSTRACT

Embodiments of the disclosure disclose a gate driving circuit, a driving method, and a display device. In the gate driving circuit, the input module transmits the input signal of the input signal terminal to the first node. The reset module resets the first node and the output terminal of the gate driving circuit. The pull-down module pulls down the signal of the first node and the signal of the output terminal of the gate driving circuit to low level signals. The pull-down control module generates a voltage signal of the second node based on the signal of the noise-canceling signal terminal, and controls the pull-down module to pull down a high level noise signal at the first node to a low level signal using the voltage signal. The pull-up module pulls up the signal of the output terminal of the gate driving circuit to a high level signal.

### CROSS-REFERENCE TO RELATED APPLICATIONS

The present application is the U.S. national phase entry of PCT/CN2016/100315, with an international filling date of Sep. 27, 2016, which claims the benefit of Chinese Patent Application NO. 201610009563.6, filed on Jan. 7, 2016, the entire disclosure of which is incorporated herein by reference.

### FIELD OF THE INVENTION

The present disclosure relates to the field of display technology, and particularly to a gate driving circuit, a driving method, and a display device.

### BACKGROUND

The liquid crystal panel is one of the important components of a display device, which includes rows and columns of pixel units. When the liquid crystal panel is in operation, the gate driving signal controls the thin film transistors (TFT) in the pixel unit to be turned on and off, so as to carry out row scanning for the liquid crystal panel, thereby realizing the image displaying function of the liquid crystal panel.

The gate driving signal is generated by a gate driving circuit. Common gate driving circuits include gate on array (GOA) circuit and chip on film (COF) circuit. The GOA circuit can lead to advantages such as narrow frame, low cost, and so on, so it is widely used in the display device.

However, the TFTs in the GOA circuit are more sensitive to temperature. In a high temperature scene of the high-low temperature test for the liquid crystal panel, the noise at the node in the GOA circuit for controlling an output transistor (the output signal of the GOA circuit is supplied via the output transistor) may be amplified so that the current flowing through this node is increased. As a result, the output transistor may be turned on multiple times within one frame time, leading to the problem of multi-row output and causing a display abnormality in the liquid crystal panel.

### SUMMARY

Embodiments of the present disclosure provide a gate driving circuit, a driving method and a display device for preventing the occurrence of multi-row output and ensuring normal display of the liquid crystal panel in the display device.

An embodiment of the present disclosure provides a gate driving circuit comprising an input module, a reset module, a pull-down module, a pull-down control module and a pull-up module. The input module has an input signal terminal for receiving an input signal, the input module is electrically connected to a first node, and the input module is configured to receive the input signal and transmit the input signal to the first node. The reset module has a reset signal terminal for receiving a reset signal, the reset module is electrically connected to the first node, a reference potential terminal and an output terminal of the gate driving circuit, and the reset module is configured to reset the first node and the output terminal of the gate driving circuit based on the reset signal. The pull-down module has a first clock signal terminal for receiving a first clock signal, the pull-down module is electrically connected to a second node, the reference potential terminal, the first node and the output terminal of the gate driving circuit, and the pull-down module is configured to pull down a voltage signal of the first node and a signal of the output terminal of the gate driving circuit to a low level signal based on the first clock signal and a voltage signal of the second node. The pull-down control module has a noise-canceling signal terminal for receiving a noise-canceling signal, the pull-down control module is electrically connected to the reference potential terminal, the second node and the first node, and the pull-down control module is configured to generate the voltage signal of the second node based on the noise-canceling signal and control the pull-down module to pull down a high level noise signal at the first node to a low level signal by means of the voltage signal of the second node. The pull-up module has a second clock signal terminal for receiving a second clock signal, the pull-up module is electrically connected to the first node and the output terminal of the gate driving circuit, and the pull-up module is configured to pull up the signal of the output terminal of the gate driving circuit to a high level signal based on the second clock signal and the voltage signal of the first node.

Another embodiment of the present disclosure provides a driving method for the gate driving circuit described in the foregoing embodiment. The method comprises receiving, by the pull-down control module, the noise-canceling signal from the noise-canceling signal terminal, transmitting the noise-canceling signal to the second node as the voltage signal of the second node, and

receiving, by the pull-down module, the voltage signal of the second node and a low level signal of the reference potential terminal, transmitting the low level signal of the reference potential terminal to the first node and the output terminal of the gate driving circuit, thereby pulling down a high level noise signal at the first node to a low level signal, and outputting the low level signal by the output terminal of the gate driving circuit.

A further embodiment of the present disclosure further provides a display device comprising a plurality of cascaded gate driving circuits described in the foregoing embodiment.

### BRIEF DESCRIPTION OF THE DRAWINGS

The drawings described herein are intended to provide a further understanding to embodiments of the present disclosure, which constitute a part of the specification of the present application. The illustrative embodiments of the present disclosure and explanations thereof are intended to interpret the invention and do not limit the present invention.

In the drawings,

FIG. 1 is a block diagram of a gate driving circuit provided by an embodiment of the present disclosure.

FIG. 2 is a signal timing diagram for the gate driving circuits shown in FIGS. 1 and 3.

FIG. 3 is a schematic circuit diagram of a gate driving circuit provided by another embodiment of the present disclosure.

FIG. 4 is a schematic diagram of a plurality of cascaded gate driving circuits in a display device provided by another embodiment of the present disclosure.

FIG. 5 is a signal timing diagram for the plurality of cascaded gate driving circuits in the display device as shown in FIG. 4.

FIG. 6 is a flow chart of a driving method for the gate driving circuit provided by embodiments of the present disclosure.

### DETAILED DESCRIPTION OF EMBODIMENTS

In order to further explain the gate driving circuit, the driving method, and the display device as provided by embodiments of the present disclosure, theses embodiments will be described in detail below with reference to the accompanying drawings.

Referring to FIG. 1, a gate driving circuit provided by an embodiment of the present disclosure comprises an input module P1, a reset module P2, a pull-down module P3, a pull-down control module P4, and a pull-up module P5. The input module P1 has an input signal terminal INPUT for receiving an input signal, and is electrically connected to a first node PU. The input module P1 may be configured to receive the input signal and transmit the input signal to the first node PU. The reset module P2 has a reset signal terminal RESET for receiving a reset signal, and the reset module P2 is electrically connected to the first node PU, a reference potential terminal VSS and an output terminal OUTPUT of the gate driving circuit. The reset module P2 may be configured to reset the first node PU and the output terminal of the gate driving circuit based on the reset signal. The pull-down module P3 has a first clock signal terminal CLK1 for receiving a first clock signal, and the pull-down module P3 is electrically connected to a second node PD, the reference potential terminal VSS, the first node PU and the output terminal OUTPUT of the gate driving circuit. The pull-down module P3 may be configured to pull down the voltage of the first node PU and the signal of the output terminal OUTPUT of the gate driving circuit to a low level based on the first clock signal and the voltage of the second node PD. The pull-down control module P4 has a noise-canceling signal terminal CLK_HD for receiving a noise-canceling signal, and the pull-down control module P4 is electrically connected to the reference potential terminal VSS, the second node PD and the first node PU. The pull-down control module P4 may be configured to generate a voltage signal of the second node PD based on the noise-canceling signal, and control the pull-down module P3 to pull down a high level noise signal at the first node PU to a low level signal using the voltage signal of the second node PD. The pull-up module P5 has a second clock signal terminal CLK2 for receiving a second clock signal, and the pull-up module P5 is electrically connected to the first node PU and the output terminal OUTPUT of the gate driving circuit. The pull-up module P5 may be configured to pull up the signal of the output terminal OUTPUT of the gate driving circuit to a high level signal based on the second clock signal and the voltage signal of the first node PU.

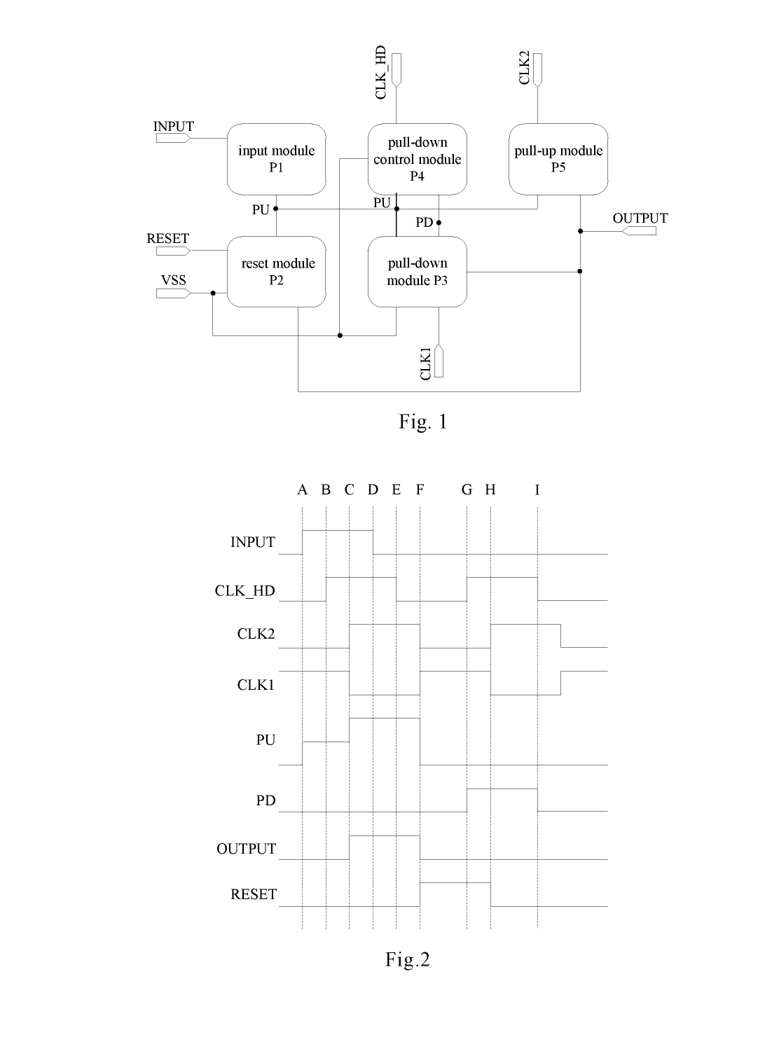

Referring to FIG. 2, FIG. 2 is a signal timing diagram corresponding to the gate driving circuit shown in FIG. 1. The operation process of the above gate driving circuit will be described below with reference to the gate driving circuit described in the foregoing embodiment based on an example in which the operation signal for each module are high level signals. The operation process of the above gate driving circuit may include the following phases.

In the phase A-B, the input signal of the input signal terminal INPUT and the first clock signal of the first clock signal terminal CLK1 are both high level signals, and the second clock signal of the second clock signal terminal CLK2, the noise-canceling signal of the noise-canceling signal terminal CLK_HD and the reset signal of the reset signal terminal RESET are all low level signals. The input module P1 receives the high level signal of the input signal terminal INPUT and transmits the high level signal to the first node PU. The pull-up module P5 receives the high level signal of the first node PU and the low level signal of the second clock signal terminal CLK2, and transmits the low level signal of the second clock signal terminal CLK2 to the output terminal OUTPUT of the gate driving circuit. The pull-down module P3 receives the high level signal of the first clock signal terminal CLK1 and the low level signal of the reference potential terminal VSS, and transmits the low level signal of the reference potential terminal VSS to the output terminal OUTPUT of the gate driving circuit. Thus, the output terminal OUTPUT of the gate driving circuit outputs a low level signal.

In the phase B-C, the input signal of the input signal terminal INPUT, the noise-canceling signal of the noise-canceling signal terminal CLK_HD, and the first clock signal of the first clock signal terminal CLK1 are high level signals, and the second clock signal of the second clock signal terminal CLK2 and the reset signal of the reset signal terminal RESET are low level signals. The input module P1 receives the high level signal of the input signal terminal INPUT and transmits the high level signal to the first node PU. The pull-up module P5 receives the high level signal of the first node PU and the low level signal of the second clock signal terminal CLK2, and transmits the low level signal of the second clock signal terminal CLK2 to the output terminal OUTPUT of the gate driving circuit. The pull-down control module P4 receives the high level signal of the noise-canceling signal terminal CLK_HD and the low level signal of the reference potential terminal VSS, and transmits the low level signal of the reference potential terminal VSS to the second node PD. The pull-down module P3 receives the high level signal of the first clock signal terminal CLK1 and the low level signal of the reference potential terminal VSS, and transmits the low level signal of the reference potential terminal VSS to the output terminal OUTPUT of the gate driving circuit. The output terminal OUTPUT of the gate driving circuit outputs a low level signal.

In the phase C-D, the input signal of the input signal terminal INPUT, the noise-canceling signal of the noise-canceling signal terminal CLK_HD, and the second clock signal of the second clock signal terminal CLK2 are all high level signals, and the first clock signal of the first clock signal terminal CLK1 and the reset signal of the reset signal terminal RESET are both low level signals. The input module P1 receives the high level signal of the input signal terminal INPUT and transmits the high level signal of the input signal terminal INPUT to the first node PU. The pull-up module P5 receives the high level signal of the first node PU and the high level signal of the second clock signal terminal CLK2, and transmits the high level signal of the second clock signal terminal CLK2 to the output terminal OUTPUT of the gate driving circuit. The pull-down module P3 receives the low level signal of the first clock signal terminal CLK1 and does not operate. The output terminal OUTPUT of the gate driving circuit outputs a high level signal.

In the phase D-E, the noise-canceling signal of the noise-canceling signal terminal CLK_HD and the second clock signal of the second clock signal terminal CLK2 are both high level signals, and the input signal of the input signal terminal INPUT, the first clock signal of the first clock signal terminal CLK1 and the reset signal of the reset signal terminal RESET signal are all low level signals. The input module P1 receives the low level signal of the input signal terminal INPUT and does not operate. The pull-up module P5 may maintain the high level signal at the first node PU by means of the bootstrap effect. The pull-down control module P4 receives the high level signal of the first node PU and the low level signal of the reference potential terminal VSS, and transmits the low level signal of the reference potential terminal VSS to the second node PD. The pull-down module P3 receives the low level signal of the second node PD and the low level signal of the first clock signal terminal CLK1, and the pull-down module P3 does not operate. The pull-up module P5 receives the high level signal of the first node PU and the high level signal of the second clock signal terminal CLK2, and transmits the high level signal of the second clock signal to the output terminal OUTPUT of the gate driving circuit. The output terminal OUTPUT of the gate driving circuit outputs a high level signal.

In the phase E-F, the second clock signal of the second clock signal terminal CLK2 is a high level signal, and the noise-canceling signal of the noise-canceling signal terminal CLK_HD, the input signal of the input signal terminal INPUT, the first clock signal of the first clock signal terminal CLK1 and the reset signal of the reset signal terminal RESET are all low level signals. The input module P1 receives the low level signal of the input signal terminal INPUT, and the input module P1 does not operate. The pull-up module P5 may maintain the high level at the first node PU by means of the bootstrap effect. The pull-down control module P4 receives the high level signal of the first node PU and the low level signal of the reference potential terminal VSS, and transmits the low level signal of the reference potential terminal VSS to the second node PD. The pull-down module P3 receives the low level signal of the second node PD and the low level signal of the first clock signal terminal CLK1, and the pull-down module P3 does not operate. The pull-up module P5 receives the high level signal of the first node PU and the high level signal of the second clock signal terminal CLK2, and transmits the high level signal of the second clock signal terminal CLK2 to the output terminal OUTPUT of the gate driving circuit. The output terminal OUTPUT of the gate driving circuit outputs a high level signal.

In the phase F-G, the first clock signal of the first clock signal terminal CLK1 and the reset signal of the reset signal terminal RESET are both high level signals, and the noise-canceling signal of the noise-canceling signal terminal CLK_HD, the input signal of the input signal terminal INPUT and the second clock signal of the second clock signal terminal CLK2 are all low level signals. The input module P1 receives the low level signal of the input signal terminal INPUT, and the input module P1 does not operate. The pull-down module P3 receives the high level signal of the first clock signal terminal CLK1 and the low level signal of the reference potential terminal VSS, and transmits the low level signal of the reference potential terminal VSS to the output terminal OUTPUT of the gate driving circuit. The reset module P2 receives the high level signal of the reset signal terminal RESET and the low level signal of the reference potential terminal VSS, transmits the low level signal of the reference potential terminal VSS to the first node PU, and transmits the low level signal of the reference potential terminal VSS to the output terminal OUTPUT of the gate driving circuit. The output terminal OUTPUT of the gate driving circuit outputs a low level signal.

In the phase G-H, the noise-canceling signal of the noise-canceling signal terminal CLK_HD, the first clock signal of the first clock signal terminal CLK1 and the reset signal of the reset signal terminal RESET are all high level signals, and the input signal of the input signal terminal INPUT and the second clock signal of the second clock signal terminal CLK2 are both low level signals. The input module P1 receives the low level signal of the input signal terminal INPUT and does not operate. The reset module P2 receives the high level signal of the reset signal terminal RESET and the low level signal of the reference potential terminal VSS, transmits the low level signal of the reference potential terminal VSS to the first node PU, and transmits the low level signal of the reference potential terminal VSS to the output terminal OUTPUT of the gate driving circuit. The pull-down control module P4 receives the low level signal of the first node PU and the high level signal of the noise-canceling signal terminal CLK_HD, and transmits the high level signal of the noise-canceling signal terminal CLK_HD to the second node PD. The pull-down module P3 receives the high level signal of the second node PD, the high level signal of the first clock signal terminal CLK1 and the low level signal of the reference potential terminal VSS, and transmits the low level signal of the reference potential terminal VSS to the output terminal OUTPUT of the gate driving circuit. The output terminal OUTPUT of the gate driving circuit outputs a low level signal.

In the phase H-I, the noise-canceling signal of the noise-canceling signal terminal CLK_HD and the second clock signal of the second clock signal terminal CLK2 are both high level signals, and the reset signal of the reset signal terminal RESET, the input signal of the input signal terminal INPUT and the first clock signal of the first clock signal terminal CLK1 are all low level signals. The input module P1 receives the low level signal of the input signal terminal INPUT, and the input module P1 does not operate. The pull-down control module P4 receives the high level signal of the noise-canceling signal terminal CLK_HD and transmits the high level signal of the noise-canceling signal terminal CLK_HD to the second node PD so that the voltage signal of the second node PD is a high level signal. The pull-down module P3 receives the high level signal of the second node PD and the low level signal of the reference potential terminal VSS, and transmits the low level signal of the reference potential terminal VSS to the first node PU and the output terminal OUTPUT of the gate driving circuit, so as to pull down the signal at the first node PU to a low level signal, i.e. pulling down the high level noise signal that may be generated at the first node PU to a low level signal, thereby preventing generation of the high level noise signal at the first node PU and suppressing the current at the first node PU. The output terminal OUTPUT of the gate driving circuit outputs a low level signal, which prevents the output terminal OUTPUT of the gate driving circuit from outputting a high level signal again.

The gate driving circuit provided by the embodiment of the present disclosure comprises an input module P1, a reset module P2, a pull-down module P3, a pull-down control module P4 and a pull-up module P5. As compared to the gate driving circuit in the prior art, the pull-down control module P4 in the embodiment of the present disclosure can generate a voltage signal of the second node PD based on the noise-canceling signal of the noise-canceling signal terminal CLK_HD, and control the pull-down module P3 to pull down the high level noise signal that may occur at the first node PU to a low level signal by means of the voltage signal of the second node PD, so as to eliminate the noise and prevent the noise at the first node PU from being amplified to cause an increase in the current of the first node PU, thereby avoiding the problem of multi-row output and ensuring normal displaying of the liquid crystal panel in the display device.

In the above embodiment, the input module P1 may receive the input signal of the input signal terminal INPUT and transmit the input signal of the input signal terminal INPUT to the first node PU. The reset module P2 may reset the first node PU and the output terminal OUTPUT of the gate driving circuit based on the reset signal of the reset signal terminal RESET. The pull-down module P3 may pull down the voltage signal of the first to node PU and the signal of the output terminal OUTPUT of the gate driving circuit to low level signals based on the first clock signal of the first clock signal terminal CLK1 and the voltage signal of the second node PD. The pull-down control module P4 may generate a voltage signal at the second node PD based on the noise-canceling signal and control the pull-down module P3 to pull down the high level noise signal at the first node PU to a low level signal by means of the voltage signal at the second node PD. The pull-up module P5 may pull up the signal of the output terminal OUTPUT of the gate driving circuit to a high level signal based on the second clock signal of the second clock signal terminal CLK2 and the voltage signal of the first node PU. In the embodiments of the present disclosure, the input signal received at the input signal terminal INPUT may be a frame start signal STV.

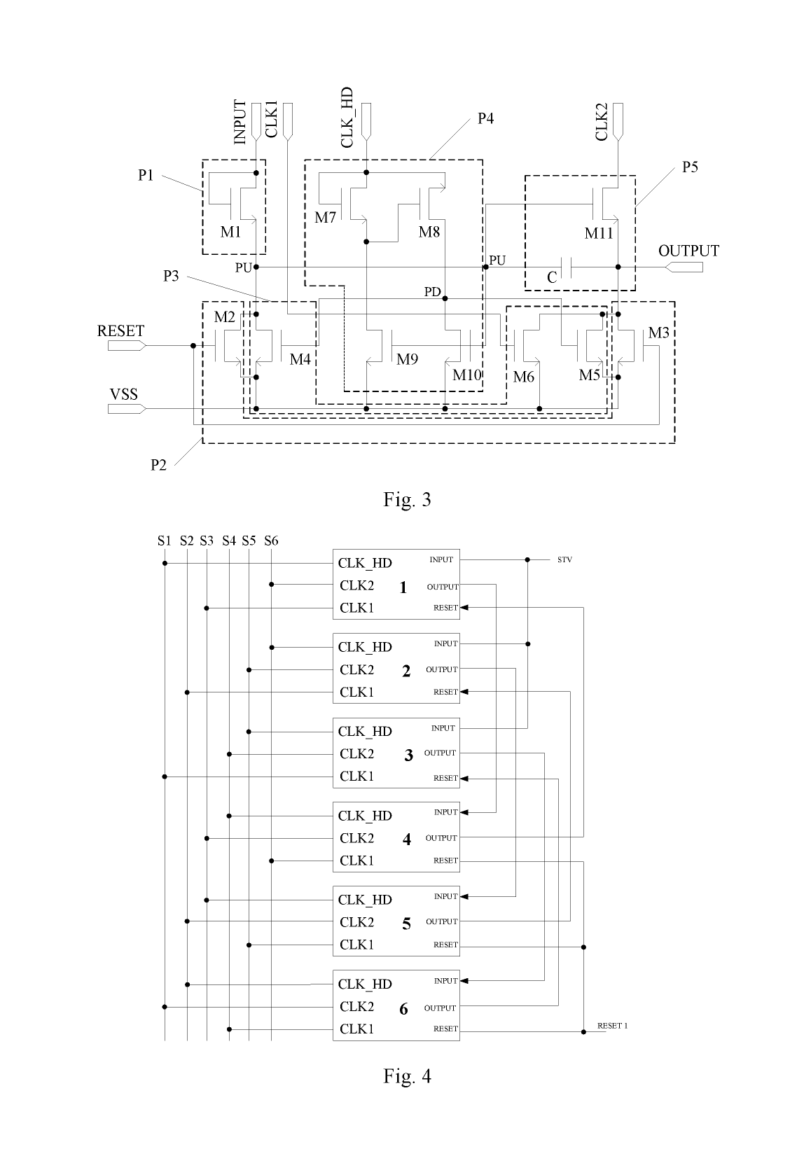

Referring to FIG. 3, the circuit configuration of the input module P1, the reset module P2, the pull-down module P3, the pull-down control module P4, and the pull-up module P5 in the embodiment will be described in detail below by way of example. As shown in FIG. 3, the input module P1 comprises a first transistor M1. The control terminal and a first terminal of the first transistor M1 are both connected to the input signal terminal INPUT, and a second terminal of the first transistor M1 is connected to the first node PU.

The reset module P2 comprises a second transistor M2 and a third transistor M3. The control terminal of the second transistor M2 is connected to the reset signal terminal RESET, a first terminal of the second transistor M2 is connected to the first node PU, and a second terminal of the second transistor M2 is connected to the reference potential terminal VSS. The control terminal of the third transistor M3 is connected to the reset signal terminal RESET, a first terminal of the third transistor M3 is connected to the output terminal OUTPUT of the gate driving circuit, and a second terminal of the third transistor M3 is connected to the reference potential terminal VSS.

The pull-down module P3 comprises a fourth transistor M4, a fifth transistor M5, and a sixth transistor M6. The control terminal of the fourth transistor M4 is connected to the second node PD, a first terminal of the fourth transistor M4 is connected to the first node PU, and a second terminal of the fourth transistor M4 is connected to the reference potential terminal VSS. The control terminal of the fifth transistor M5 is connected to the second node PD, a first terminal of the fifth transistor M5 is connected to the output terminal OUTPUT of the gate driving circuit, and a second terminal of the fifth transistor M5 is connected to the reference potential terminal VSS. The control terminal of the sixth transistor M6 is connected to the first clock signal terminal CLK1, a first terminal of the sixth transistor M6 is connected to the output terminal OUTPUT of the gate driving circuit, and a second terminal of the sixth transistor M6 is connected to the reference potential terminal VSS.

The pull-down control module P4 comprises a seventh transistor M7, an eighth transistor M8, a ninth transistor M9, and a tenth transistor M10. The control terminal and a first terminal of the seventh transistor M7 are both connected to the noise-canceling signal terminal CLK_HD, and a second terminal of the seventh transistor M7 is connected to the control terminal of the eighth transistor M8 and a first terminal of the ninth transistor M9. A first terminal of the eighth transistor M8 is connected to the second node PD, and a second terminal of the eighth transistor M8 is connected to the noise-canceling signal terminal CLK_HD. The control terminal of the ninth transistor M9 is connected to the first node PU, and the second terminal of the ninth transistor M9 is connected to the reference potential terminal VSS. The control terminal of the tenth transistor M10 is connected to the first node PU, a first terminal of the tenth transistor M10 is connected to the second node PD, and a second terminal of the tenth transistor M10 is connected to the reference potential terminal VSS.

The pull-up module P5 comprises an eleventh transistor M11 and a bootstrap capacitor C. The control terminal of the eleventh transistor M11 is connected to the first node PU, a first terminal of the eleventh transistor M11 is connected to the second clock signal terminal CLK2, and a second terminal of the eleventh transistor M11 is connected to the output terminal OUTPUT of the gate driving circuit. A first terminal of the bootstrap capacitor C is connected to the first node PU, and a second terminal of the bootstrap capacitor C is connected to the output terminal OUTPUT of the gate driving circuit.

It is to be noted that, in this disclosure, the first and second terminals of a transistor in each module refer to two terminals, i.e., the source and the drain, except for the control terminal (e.g., gate) of the transistor. Depending on the type of transistor, the source and the drain of the transistor may be connected in different manners, thus the first terminal and the second terminal as mentioned are interchangeable. That is, the first terminal of each of the transistors may be the source, and the second terminal may be the drain. Alternatively, the first terminal may be the drain, and the second terminal may be the source. In the embodiment shown in FIG. 3, the gate driving circuit is described with an example in which the transistors are N-type transistors, and the second terminal is the source and the first terminal is the drain. However, the transistors may also be P-type transistors. The circuit configuration with P-type transistors also falls within the scope of the present application.

The operation process of the gate driving circuit shown in FIG. 3 will be described below with reference to FIG. 2 based on an example in which the transistors are N-type transistors, and the signal of the first clock signal terminal CLK1 and the signal of the second clock signal terminal CLK2 are signals with opposite phases.

In the phase A-B, the signal of the input signal terminal INPUT and the signal of the first clock signal terminal CLK1 are both high level signals, and the signal of the second clock signal terminal CLK2, the signal of the noise-canceling signal terminal CLK_HD and the signal of the reset signal terminal RESET are all low level signals. The gate of the first transistor M1 receives the high level signal of the input signal terminal INPUT, thus the first transistor M1 is turned on, the high level signal at the drain of the first transistor M1 is transmitted to the source of the first transistor M1. The source of the first transistor M1 is connected to the first node PU, so the first node PU charges the bootstrap capacitor C. The gate of the ninth transistor M9, the gate of the tenth transistor M10, and the gate of the eleventh transistor M11 receive the high level signal at the first node PU, the ninth transistor M9, the tenth transistor M10, and the eleventh transistor M11 are turned on, so that the tenth transistor M10 transmits the low level signal of the reference potential terminal VSS of the source thereof to the drain of the tenth transistor M10, which is connected to the second node PD. The gate of the fourth transistor M4 and the gate of the fifth transistor M5 receive the low level signal of the second node PD, and the fourth transistor M4 and the fifth transistor M5 are both turned off. The low level signal of the second clock signal terminal CLK2 is transmitted from the drain of the eleventh transistor M11 to the source thereof. The gate of the sixth transistor M6 receives the high level signal of the first clock signal terminal CLK1 and is turned on. The sixth transistor M6 transmits the low level signal of the reference potential terminal VSS to the drain of the sixth transistor M6. The source of the eleventh transistor M11 is connected to the output terminal OUTPUT of the gate driving circuit, the drain of the sixth transistor M6 is connected to the output terminal OUTPUT of the gate driving circuit, and the output terminal OUTPUT of the gate driving circuit outputs a low level signal.

In the phase B-C, the signal of the input signal terminal INPUT, the signal of the noise-canceling signal terminal CLK_HD and the signal of the first clock signal terminal CLK1 are all high level signals, and the signal of the second clock signal terminal CLK2 and the signal of the reset signal terminal RESET are both low level signals. The gate of the first transistor M1 receives the high level signal of the input signal terminal INPUT, the first transistor M1 is turned on, the high level signal of the input signal terminal INPUT is transmitted from the drain of the first transistor M1 to the source of the first transistor M1. The source of the first transistor M1 is connected to the first node PU, thus the high level signal at the first node PU charges the bootstrap capacitor C. The gate of the ninth transistor M9, the gate of the tenth transistor M10, and the gate of the eleventh transistor M11 receive the high level signal at the first node PU, and all of them are turned on. The gate of the seventh transistor M7 receives the high level signal of the noise-canceling signal terminal CLK_HD, the seventh transistor M7 is turned on, but the signal of the source of the seventh transistor M7 is pulled down to a low level because the ninth transistor M9 is turned on. The low level signal of the reference potential terminal VSS is transmitted from the source of the tenth transistor M10 to the drain of the tenth transistor M10, which is connected to the second node PD. The gate of the fourth transistor M4 and the gate of the fifth transistor M5 receive the low level signal of the second node PD, so the fourth transistor M4 and the fifth transistor M5 are both turned off. The low level signal of the second clock signal terminal CLK2 is transmitted from the drain of the eleventh transistor M11 to the source of the eleventh transistor M11. The gate of the sixth transistor M6 receives the high level signal of the first clock signal terminal CLK1, the sixth transistor M6 is turned on, and the low level signal of the reference potential terminal VSS is transmitted from the source of the sixth transistor M6 to the drain of the sixth transistor M6. The source of the eleventh transistor M11 is connected to the output terminal OUTPUT of the gate driving circuit, and the drain of the sixth transistor M6 is connected to the output terminal OUTPUT of the gate driving circuit. Hence, the output terminal OUTPUT of the gate driving circuit outputs a low level signal.

In the phase C-D, the signal of the input signal terminal INPUT, the signal of the noise-canceling signal terminal CLK_HD and the signal of the second clock signal terminal CLK2 are all high level signals, and the signal of the first clock signal terminal CLK1 and the signal of the reset signal terminal RESET are both low level signals. The gate of the first transistor M1 receives the high level signal of the input signal terminal INPUT, the first transistor M1 is turned on, the high level signal of the input signal terminal INPUT is transmitted from the drain of the first transistor M1 to the source of the first transistor M1, which is connected to the first node PU. The gate of the ninth transistor M9, the gate of the tenth transistor M10, and the gate of the eleventh transistor M11 receive the high level signal of the first node PU, and the ninth transistor M9, the tenth transistor M10, and the eleventh transistor M11 are all turned on. The gate of the seventh transistor M7 receives the high level signal of the noise-canceling signal terminal CLK_HD, the seventh transistor M7 is turned on, but the signal of the source of the seventh transistor M7 is pulled down to a low level signal because the ninth transistor M9 is also turned on. The low level signal of the reference potential terminal VSS is transmitted from the source of the tenth transistor M10 to the drain of the tenth transistor M10, which is connected to the second node PD. The gate of the fourth transistor M4 and the gate of the fifth transistor M5 receive the low level signal at the second node PD, and the fourth transistor M4 and the fifth transistor M5 are both turned off. The gate of the sixth transistor M6 receives the low level signal of the first clock signal terminal CLK1, and the sixth transistor M6 is turned off. The high level signal of the second clock signal terminal CLK2 is transmitted from the drain of the eleventh transistor M11 to the source of the eleventh transistor M11, which is connected to the output terminal OUTPUT of the gate driving circuit. Therefore, the output terminal OUTPUT of the gate driving circuit outputs a high level signal.

In the phase D-E, the signal of the noise-canceling signal terminal CLK_HD and the signal of the second clock signal terminal CLK2 are both high level signals, and the signal of the input signal terminal INPUT, the signal of the first clock signal terminal CLK1 and the signal of the reset signal terminal RESET are all low level signals. The gate of the first transistor M1 receives the low level signal of the input signal terminal INPUT, and the first transistor M1 is turned off. The bootstrap capacitor C maintains the high level signal at the first node PU due to the bootstrap effect. The gate of the ninth transistor M9, the gate of the tenth transistor M10, and the gate of the eleventh transistor M11 receive the high level signal of the first node PU, and the ninth transistor M9, the tenth transistor M10, and the eleventh transistor M11 are turned on. The gate of the seventh transistor M7 receives the high level signal of the noise-canceling signal terminal CLK_HD, the seventh transistor M7 is turned on, but the signal of the source of the seventh transistor M7 is pulled down to a low level signal because the ninth transistor M9 is also turned on. The low level signal of the reference potential terminal VSS is transmitted from the source of the tenth transistor M10 to the drain of the tenth transistor M10, which is connected to the second node PD. The gate of the fourth transistor M4 and the gate of the fifth transistor M5 receive the low level signal at the second node PD, the fourth transistor M4 and the fifth transistor M5 are both turned off. The gate of the sixth transistor M6 receives the low level signal of the first clock signal terminal CLK1, and the sixth transistor M6 is turned off. The high level signal of the second clock signal terminal CLK2 is transmitted from the drain of the eleventh transistor M11 to the source of the eleventh transistor M11, which is connected to the output terminal OUTPUT of the gate driving circuit. Thus, the output terminal OUTPUT of the gate driving circuit outputs a high level signal.

In the phase E-F, the signal of the second clock signal terminal CLK2 is a high level signal, and the signal of the noise-canceling signal terminal CLK_HD, the signal of the input signal terminal INPUT, the signal of the first clock signal terminal CLK1 and the signal of the reset signal terminal RESET are all low level signals. The gate of the first transistor M1 receives the low level signal of the input signal terminal INPUT, and the first transistor M1 is turned off. The bootstrap capacitor C maintains the high level signal at the first node PU due to its bootstrap effect. The gate of the ninth transistor M9, the gate of the tenth transistor M10, and the gate of the eleventh transistor M11 receive the high level signal of the first node PU, and the ninth transistor M9, the tenth transistor M10, and the eleventh transistor M11 are turned on. The reference potential terminal VSS is transmitted from the source of the tenth transistor M10 to the drain of the tenth transistor M10, which is connected to the second node PD. The gate of the fourth transistor M4 and the gate of the fifth transistor M5 receive the low level signal of the second node PD, and the fourth transistor M4 and the fifth transistor M5 are turned off. The gate of the sixth transistor M6 receives the low level signal of the first clock signal terminal CLK1, and the sixth transistor M6 is turned off. The high level signal of the second clock signal terminal CLK2 is transmitted from the drain of the eleventh transistor M11 to the source of the eleventh transistor M11, which is connected to the output terminal OUTPUT of the gate driving circuit. Hence, the output terminal OUTPUT of the gate driving circuit outputs a high level signal.

In the phase F-G, the signal of the first clock signal terminal CLK1 and the signal of the reset signal terminal RESET are both high level signals, and the signal of the noise-canceling signal terminal CLK_HD, the signal of the input signal terminal INPUT and the signal of the second clock signal terminal CLK2 are all low level signals. The gate of the first transistor M1 receives the low level signal of the input signal terminal INPUT, and the first transistor M1 is turned off. The gate of the second transistor M2 and the gate of the third transistor M3 both receive the high level signal of the reset signal terminal RESET, and they are both turned on. The low level signal of the reference potential terminal VSS is transmitted from the source of the second transistor M2 to the drain of the second transistor M2, which is connected to the first node PU. The low level signal of the reference potential terminal VSS is also transmitted from the source of the third transistor M3 to the drain of the third transistor M3, which is connected to the output terminal OUTPUT of the gate driving circuit. The gate of the sixth transistor M6 receives the high level signal of the first clock signal terminal CLK1, the sixth transistor M6 is turned on, and the low level signal of the reference potential terminal VSS is transmitted from the source of the sixth transistor M6 to the drain of the sixth transistor M6, which is connected to the output terminal OUTPUT of the gate driving circuit. The output terminal OUTPUT of the gate driving circuit outputs a low level signal.

In the phase G-H, the signal of the noise-canceling signal terminal CLK_HD, the signal of the first clock signal terminal CLK1 and the signal of the reset signal terminal RESET are all high level signals, and the signal of the input signal terminal INPUT and the signal of the second clock signal terminal CLK2 are both low level signals. The gate of the first transistor M1 receives the low level signal of the input signal terminal INPUT, and the first transistor M1 is turned off. The gate of the second transistor M2 and the gate of the third transistor M3 both receive the high level signal of the reset signal terminal RESET, and the second transistor M2 and the third transistor M3 are both turned on. The low level signal of the reference potential terminal VSS is transmitted from the source of the second transistor M2 to the drain of the second transistor M2, which is connected to the first node PU. The gate of the ninth transistor M9 and the gate of the tenth transistor M10 receive the low level signal of the first node PU, and they are both turned off. The gate of the seventh transistor M7 receives the high level signal of the noise-canceling signal terminal CLK_HD, the seventh transistor M7 is turned on. The high level signal of the noise-canceling signal terminal CLK_HD is transmitted from the drain of the seventh transistor M7 to the gate of the eighth transistor M8, thus the eighth transistor M8 is turned on. The high level signal of the noise-canceling signal terminal CLK_HD is transmitted from the source of the eighth transistor M8 to the drain of the eighth transistor M8, which is connected to the second node PD. The gate of the fourth transistor M4 and the gate of the fifth transistor M5 receive the high level signal of the second node PD, the fourth transistor M4 and the fifth transistor M5 are both turned on. The fourth transistor M4 pulls down the signal at the first node PU to a low level signal so as to prevent the eleventh transistor M11 from being turned on again, and the fifth transistor M5 pulls down the signal of the output terminal OUTPUT of the gate driving circuit to a low level signal. The low level signal of the reference potential terminal VSS is transmitted from the source of the third transistor M3 to the drain of the third transistor M3, which is connected to the output terminal OUTPUT of the gate driving circuit. The output terminal OUTPUT of the gate driving circuit outputs a low level signal.

In the phase H-I, the signal of the noise-canceling signal terminal CLK_HD and the signal of the second clock signal terminal CLK2 are both high level signals, and the signal of the reset signal terminal RESET, the signal of the input signal terminal INPUT and the signal of the first clock signal terminal CLK1 are all low level signals. The gate of the first transistor M1 receives the low level signal of the input signal terminal INPUT, and the first transistor M1 is turned off. The gate of the second transistor M2 and the gate of the third transistor M3 both receive the low level signal of the reset signal terminal RESET, and they are both turned off. The gate of the sixth transistor M6 receives the low level signal of the first clock signal terminal CLK1, and the sixth transistor M6 is turned off. The gate of the seventh transistor M7 receives the high level signal of the noise-canceling signal terminal CLK_HD, the seventh transistor M7 is turned on. The high level signal of the noise-canceling signal terminal CLK_HD is transmitted from the drain of the seventh transistor M7 to the gate of the eighth transistor M8, and the eighth transistor M8 is turned on. The high level signal of the noise-canceling signal terminal CLK_HD is transmitted from the source of the eighth transistor M8 to the drain of the eighth transistor M8, which is connected to the second node PD. The gate of the fourth transistor M4 and the gate of the fifth transistor M5 receive the high level signal of the second node PD, the fourth transistor M4 and the fifth transistor M5 are both turned on. The fourth transistor M4 pulls down the signal of the first node PU to a low level signal so as to prevent the eleventh transistor M11 from being turned on again, and the fifth transistor M5 pulls down the signal of the output terminal OUTPUT of the gate driving circuit to a low level signal. Therefore, the output terminal OUTPUT of the gate driving circuit outputs a low level signal, thereby preventing the output terminal OUTPUT of the gate driving circuit from outputting a high level signal at that time.

In a high temperature scene, the peak of the amplified high level noise signal at the first node PU is often corresponding to a rising edge of the second clock signal of the second clock signal terminal CLK2. Therefore, in embodiments of the present disclosure, a rising edge of the noise-canceling signal of the noise-canceling signal terminal CLK_HD precedes the rising edge of the second clock signal of the second clock signal terminal CLK2 by the time for driving one row of pixel units (i.e., the time required for scanning one row of pixel units). For example, as shown in FIG. 2, the rising edge of the noise-canceling signal of the noise-canceling signal terminal CLK_HD precedes the rising edge of the second clock signal of the second clock signal terminal CLK2 by the time occupied by the phase B-C (the time for driving one row of pixel units).

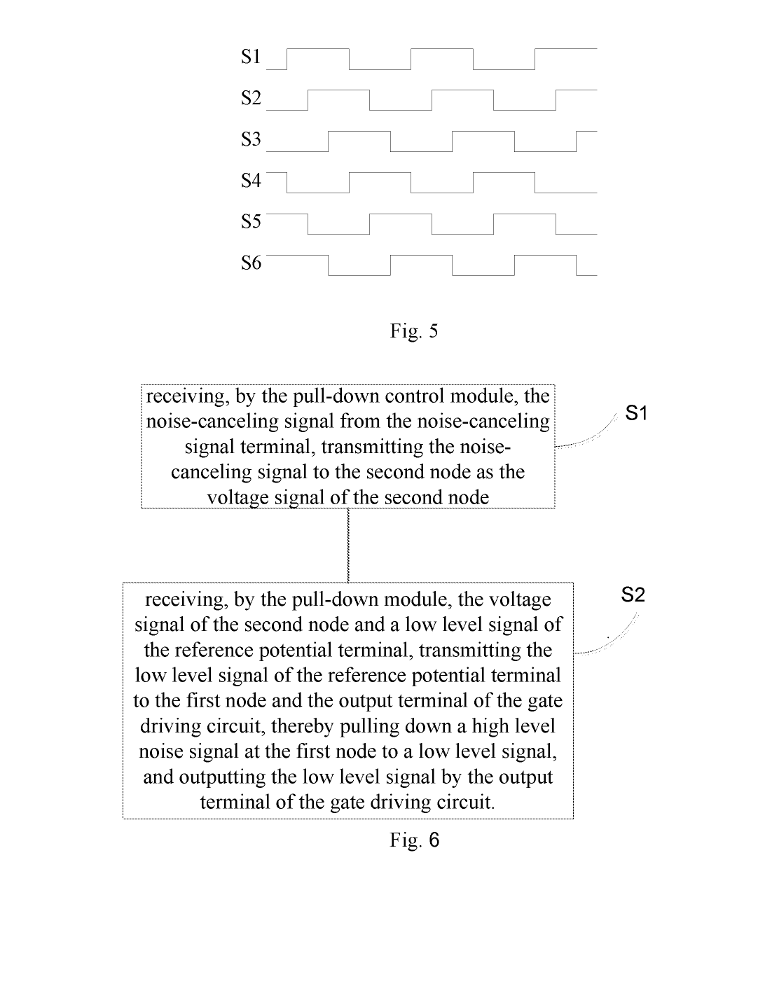

Another embodiment of the present disclosure provides a display device that may include a plurality of cascaded gate driving circuits as described in the foregoing embodiment. Referring to FIG. 4 which schematically shows a gate driving circuit group including a plurality of cascaded gate driving circuits provided by embodiments of the present disclosure, in this example, the gate driving circuit group is provided with six clock signals S1-S6, the signal timing of which is shown in FIG. 5. The rising edge of the clock signal S1 precedes the rising edge of the clock signal S2 by the time for driving one row of pixel units, the rising edge of the clock signal S2 precedes the rising edge of the clock signal S3 by the time for driving one row of pixel units, and the relationships between other clock signals S4-S6 are similar. The gate driving circuit group shown in FIG. 4 includes six gate driving circuits, and the details for cascading the gate driving circuits in the gate driving circuit group is shown in FIG. 4. The input signal terminals INPUT of the gate driving circuit 1, the gate driving circuit 2 and the gate driving circuit 3 may receive a frame start signal STV, the input signal terminal INPUT of the gate driving circuit 4 receives the output signal of the output terminal OUTPUT of the gate driving circuit 1, the input signal terminal INPUT of the gate driving circuit 5 receives the output signal of the output terminal OUTPUT of the gate driving circuit 2, and the input signal terminal INPUT of the gate driving circuit 6 receives the output signal of the output terminal OUTPUT of the gate driving circuit 3. The reset signal terminal RESET of the gate driving circuit 1 receives the output signal of the output terminal OUTPUT of the gate driving circuit 4 as a reset signal, the reset signal terminal RESET of the gate driving circuit 2 receives the output signal of the output terminal OUTPUT of the gate driving circuit 5 as a reset signal, and the reset signal terminal RESET of the gate driving circuit 3 receives the output signal of the output terminal OUTPUT of the gate driving circuit 6 as a reset signal. The gate driving circuit 4, the gate driving circuit 5 and the gate driving circuit 6 may receive an additional reset signal RESET 1 as their reset signals. Although FIG. 4 shows six gate driving circuits, in other embodiments, more cascaded gate driving circuits may be included, and the cascaded relationship between them may be derived with reference to FIG. 4. That is, the output signal of the output terminal OUTPUT of the k-th gate driving circuit may serve as the input signal of the input signal terminal INTPUT of the (k+3)-th gate driving circuit, and the output signal of the output terminal OUTPUT of the (k+3)-th gate driving circuit may serve as the reset signal for the k-th gate driving circuit. However, for the first three gate driving circuits (i.e., the first, second and third gate driving circuits), they may receive the frame start signal STV as an input signal. For the last three gate driving circuits, the reset signal terminals thereof may receive an additional external reset signal (e.g., reset signal RESET 1).

In the embodiment shown in FIG. 4, the rising edge of the signal of the noise-canceling signal terminal of each of the gate driving circuits precedes the rising edge of the signal of the second clock signal terminal by the time for driving one row of pixel units.

A further embodiment of the present disclosure provides a driving method for the gate driving circuit as described in the foregoing embodiment. Referring to FIG. 6, the method may comprise the steps of:

S1, receiving, by the pull-down control module, the noise-canceling signal from the noise-canceling signal terminal, transmitting the noise-canceling signal to the second node as the voltage signal of the second node,

S2, receiving, by the pull-down module, the voltage signal of the second node and the low level signal of the reference potential terminal, transmitting the low level signal of the reference potential terminal to the first node and the output terminal of the gate driving circuit, thereby pulling down the high level noise signal at the first node to a low level signal, and outputting the low level signal at the output terminal of the gate driving circuit.

The display device provided by embodiments of the present disclosure may be any product or component having display function such as an electronic paper, a mobile phone, a tablet computer, a television set, a display, a notebook computer, a digital photo frame, a navigator, or the like. The plurality of cascaded gate driving circuits in the display device have the same advantages as the gate driving circuit described in the foregoing embodiment, which will not be described here for simplicity.

In the description of the above embodiments, specific features, structures, materials or characteristics may be combined in any suitable manner in any one or more embodiments or examples.

The above embodiments are only specific embodiments of the present disclosure, but the protection scope of the invention is not so limited. Variations or replacements that can be easily conceived by a person having an ordinary skill in the art within the technical scope revealed by the present disclosure shall be encompassed within the protection scope of the present invention. Thus, the scope of the invention shall be based on the scope of the claims.

1. A gate driving circuit, comprising an input module, a reset module, a pull-down module, a pull-down control module and a pull-up module,
wherein the input module has an input signal terminal for receiving an input signal, the input module is electrically connected to a first node, and the input module is configured to receive the input signal and transmit the input signal to the first node,
wherein the reset module has a reset signal terminal for receiving a reset signal, the reset module is electrically connected to the first node, a reference potential terminal and an output terminal of the gate driving circuit, and the reset module is configured to reset the first node and the output terminal of the gate driving circuit based on the reset signal,
wherein the pull-down module has a first clock signal terminal for receiving a first clock signal, the pull-down module is electrically connected to a second node, the reference potential terminal, the first node and the output terminal of the gate driving circuit, and the pull-down module is configured to pull down a voltage signal of the first node and a signal of the output terminal of the gate driving circuit to a low level signal based on the first clock signal and a voltage signal of the second node,
wherein the pull-down control module has a noise-canceling signal terminal for receiving a noise-canceling signal, the pull-down control module is electrically connected to the reference potential terminal, the second node and the first node, and the pull-down control module is configured to generate the voltage signal of the second node based on the noise-canceling signal and control the pull-down module to pull down a high level noise signal at the first node to a low level signal by means of the voltage signal of the second node,
wherein the pull-up module has a second clock signal terminal for receiving a second clock signal, the pull-up module is electrically connected to the first node and the output terminal of the gate driving circuit, and the pull-up module is configured to pull up the signal of the output terminal of the gate driving circuit to a high level signal based on the second clock signal and the voltage signal of the first node.

2. The gate driving circuit according to claim 1, wherein the input module comprises a first transistor, a control terminal and a first terminal of the first transistor being both connected to the input signal terminal, a second terminal of the first transistor being connected to the first node.

3. The gate driving circuit according to claim 1, wherein the reset module comprises a second transistor and a third transistor, a control terminal of the second transistor being connected to the reset signal terminal, a first terminal of the second transistor being connected to the first node, a second terminal of the second transistor being connected to the reference potential terminal,
a control terminal of the third transistor being connected to the reset signal terminal, a first terminal of the third transistor being connected to the output terminal of the gate driving circuit, a second terminal of the third transistor being connected to the reference potential terminal.

4. The gate driving circuit according to claim 1, wherein the pull-down module comprises a fourth transistor, a fifth transistor and a sixth transistor, a control terminal of the fourth transistor being connected to the second node, a first terminal of the fourth transistor being connected to the first node, a second terminal of the fourth transistor being connected to the reference potential terminal,
a control terminal of the fifth transistor being connected to the second node, a first terminal of the fifth transistor being connected to the output terminal of the gate driving circuit, a second terminal thereof being connected to the reference potential terminal,
a control terminal of the sixth transistor being connected to the first clock signal terminal, a first terminal of the sixth transistor being connected to the output terminal of the gate driving circuit, a second terminal of the sixth transistor being connected to the reference potential terminal.

5. The gate driving circuit according to claim 1, wherein the pull-down control module comprises a seventh transistor, an eighth transistor, a ninth transistor, and a tenth transistor,
a control terminal and a first terminal of the seventh transistor being both connected to the noise-canceling signal terminal, a second terminal of the seventh transistor being connected to a control terminal of the eighth transistor and a first terminal of the ninth transistor,
a first terminal of the eighth transistor being connected to the second node, a second terminal of the eighth transistor being connected to the noise-canceling signal terminal,
a control terminal of the ninth transistor being connected to the first node, a second terminal of the ninth transistor being connected to the reference potential terminal,
a control terminal of the tenth transistor being connected to the first node, a first terminal of the tenth transistor being connected to the second node, a second terminal of the tenth transistor being connected to the reference potential terminal.

6. The gate driving circuit according to claim 1, wherein the pull-up module comprises an eleventh transistor and a bootstrap capacitor, a control terminal of the eleventh transistor being connected to the first node, a first terminal of the eleventh transistor being connected to the second clock signal terminal, a second terminal of the eleventh transistor being connected to the output terminal of the gate driving circuit,
a first terminal of the bootstrap capacitor being connected to the first node, a second terminal of the bootstrap capacitor being connected to the output terminal of the gate driving circuit.

7. The gate driving circuit according to claim 1, wherein the first clock signal received by the first clock signal terminal and the second clock signal received by the second clock signal terminal are signals with opposite phases.

8. The gate driving circuit according to claim 1, wherein a rising edge of the noise-canceling signal received by the noise-canceling signal terminal precedes a rising edge of the second clock signal received by the second clock signal terminal by time for driving one row of pixel units.

9. A driving method for the gate driving circuit according to claim 1, wherein the method comprises:
receiving, by the pull-down control module, the noise-canceling signal from the noise-canceling signal terminal, transmitting the noise-canceling signal to the second node as the voltage signal of the second node,
receiving, by the pull-down module, the voltage signal of the second node and a low level signal of the reference potential terminal, transmitting the low level signal of the reference potential terminal to the first node and the output terminal of the gate driving circuit, thereby pulling down a high level noise signal at the first node to a low level signal, and outputting the low level signal by the output terminal of the gate driving circuit.

10. A display device comprising a plurality of cascaded gate driving circuits according claim 1.

11. The gate driving circuit according to claim 2, wherein the first clock signal received by the first clock signal terminal and the second clock signal received by the second clock signal terminal are signals with opposite phases.

12. The gate driving circuit according to claim 3, wherein the first clock signal received by the first clock signal terminal and the second clock signal received by the second clock signal terminal are signals with opposite phases.

13. The gate driving circuit according to claim 4, wherein the first clock signal received by the first clock signal terminal and the second clock signal received by the second clock signal terminal are signals with opposite phases.

14. The gate driving circuit according to claim 5, wherein the first clock signal received by the first clock signal terminal and the second clock signal received by the second clock signal terminal are signals with opposite phases.

15. The gate driving circuit according to claim 6, wherein the first clock signal received by the first clock signal terminal and the second clock signal received by the second clock signal terminal are signals with opposite phases.

16. The gate driving circuit according to claim 2, wherein a rising edge of the noise-canceling signal received by the noise-canceling signal terminal precedes a rising edge of the second clock signal received by the second clock signal terminal by time for driving one row of pixel units.

17. The gate driving circuit according to claim 3, wherein a rising edge of the noise-canceling signal received by the noise-canceling signal terminal precedes a rising edge of the second clock signal received by the second clock signal terminal by time for driving one row of pixel units.

18. The gate driving circuit according to claim 4, wherein a rising edge of the noise-canceling signal received by the noise-canceling signal terminal precedes a rising edge of the second clock signal received by the second clock signal terminal by time for driving one row of pixel units.

19. The gate driving circuit according to claim 5, wherein a rising edge of the noise-canceling signal received by the noise-canceling signal terminal precedes a rising edge of the second clock signal received by the second clock signal terminal by time for driving one row of pixel units.

20. The gate driving circuit according to claim 6, wherein a rising edge of the noise-canceling signal received by the noise-canceling signal terminal precedes a rising edge of the second clock signal received by the second clock signal terminal by time for driving one row of pixel units.
